(19) United States
(12) Patent Application Publication
(10) Pub. No.: US 2013/0250541 A1
(43) Pub. Date: Sep. 26, 2013

(54) ELECTRONIC DEVICE HAVING SENSOR WINDOW COVER

(71) Applicants: Wei LIU, Shenzhen City (CN); Xue-Dong TANG, Shenzhen City (CN)

(72) Inventors: Wei LIU, Shenzhen City (CN); Xue-Dong TANG, Shenzhen City (CN)

(73) Assignees: HON HAI PRECISION INDUSTRY CO., LTD., Tu-Cheng (TW); HONG FU JIN PRECISION INDUSTRY(ShenZhen) CO., LTD., Shenzhen City (CN)

(21) Appl. No.: 13/587,979

(22) Filed: Aug. 17, 2012

(30) Foreign Application Priority Data
Mar. 23, 2012 (CN) 201220113009.X

(51) Int. Cl. H05K 5/03

(52) U.S. Cl. 361/820

(57) ABSTRACT

An electronic device includes a housing defining an opening, a signal receiving unit received in the housing, a sensor window cover secured to the opening and corresponding to the signal receiving unit, and a stopping mechanism. The stopping mechanism includes a resisting member secured to the sensor window cover, a first stopping member and a second stopping member arranged on opposite sides of the opening. The resisting member defines a receiving portion. The receiving portion receives the first stopping member to allow the sensor window cover to be secured to the opening, and abuts the second stopping member to prevent the sensor window cover from being secured to the opening when the sensor window is installed reversely.

### BACKGROUND

1. Technical Field

The present disclosure relates to electronic devices, and particularly to an electronic device having a sensor window cover.

2. Description of Related Art

Electronic devices, such as DVD players, may include a housing, a circuit board received in the housing, a signal receiving unit arranged on the circuit board, and a sensor window cover secured to the housing and corresponding to the signal receiving unit. A sign is printed on the sensor window for identification. However, the sensor window cover may be inadvertently installed in reverse, thus the sign is also reversed.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the six views.

FIG. 1 is a partial perspective view of an electronic device having a sensor window cover in accordance with an embodiment.

FIG. 2 is a partially disassembled view of the electronic device of FIG. 1.

FIG. 3 is similar to FIG. 2, but viewed from another aspect.

FIG. 4 is an enlarged view of portion IV in FIG. 3.

FIG. 5 is an enlarged view of portion V in FIG. 2.

FIG. 6 is a partial assembly view of the electronic device of FIG. 2.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

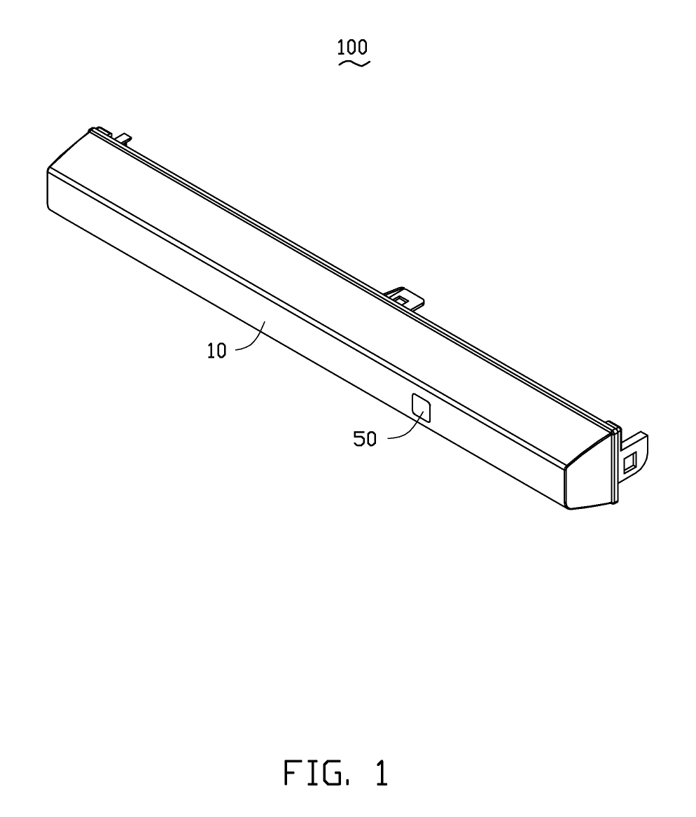

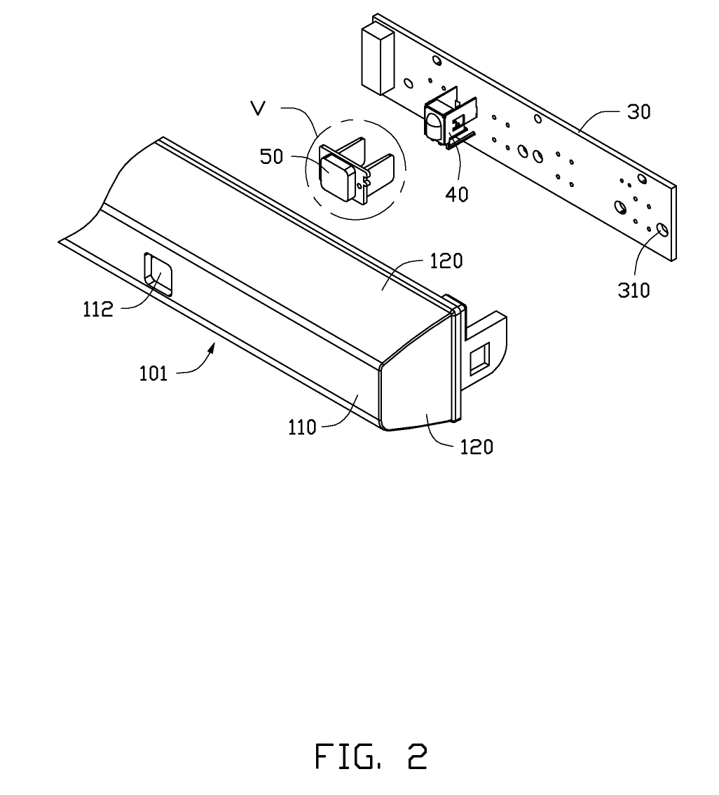

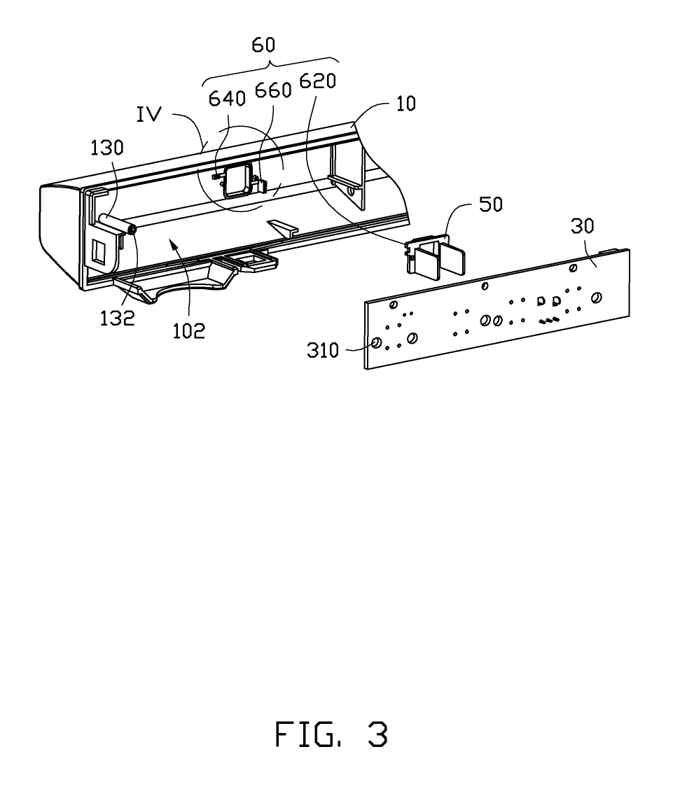

Referring to FIG. 1, an electronic device 100 having a sensor window cover 50 is shown. Referring also to FIGS. 2-3, the electronic device 100 includes a housing 10, a circuit board 30 received in the housing 10, a signal receiving unit 40 arranged on the circuit board 30, a sensor window cover 50 secured to the housing 10 and corresponding to the signal receiving unit 40, and a stopping mechanism 60 for preventing the sensor window 50 from being installed incorrectly.

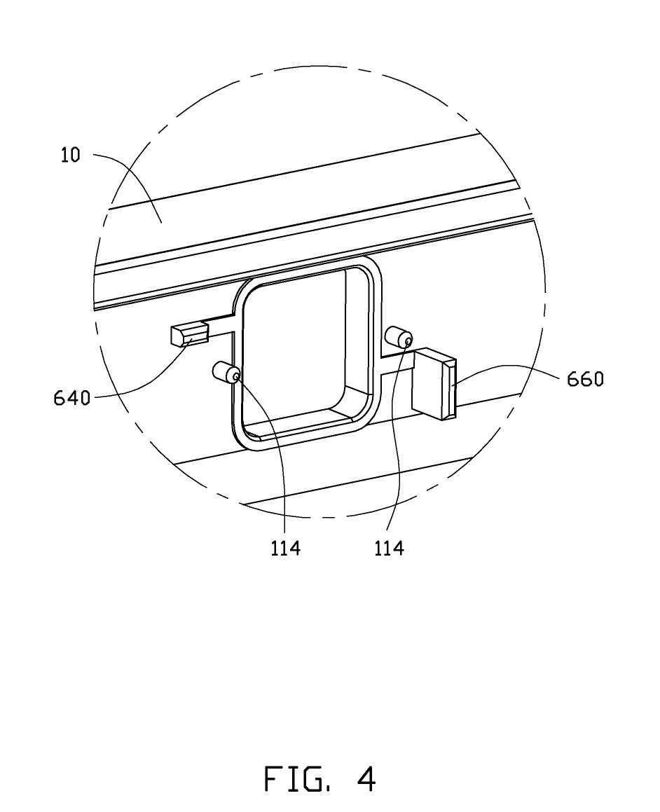

The housing 10 includes a front case 101 (see FIG. 2) and a rear case (not shown). The front case 101 engages with the rear case to define a receiving space 102 for receiving the circuit board 30, the signal receiving unit 40, and other electronic components (not shown) of the electronic device 100. The front case 101 includes a front wall 110 and a plurality of sidewalls 120 protruding from the rims of the front wall 110. The front wall 110 defines an opening 112. The opening 112 is substantially rectangular, and is used for securing the sensor window cover 50. A plurality of fixing posts 130 are secured on an inner surface of the front wall 110. Each fixing post 130 defines a fixing hole 132. Two limiting posts 114 (FIG. 4) are perpendicularly arranged on the inner surface of the front wall 110 and are symmetrically arranged on opposite sides of the opening 112. In the embodiment, the limiting posts 114 are aligned in a line (referred herein as the connecting line) extending along the length of the front wall 110.

The circuit board 30 is substantially rectangular, and is arranged parallel to the front wall 110. The circuit board 30 defines a plurality of through hole 310 corresponding to the fixing holes 132. Fixing members (such as screws, not shown) extend through the through holes 310 and are further threaded into the fixing holes 132, to fix the circuit board 30 to the front case 101. The signal receiving unit 40 is secured to the circuit board 30 and corresponds to the opening 112.

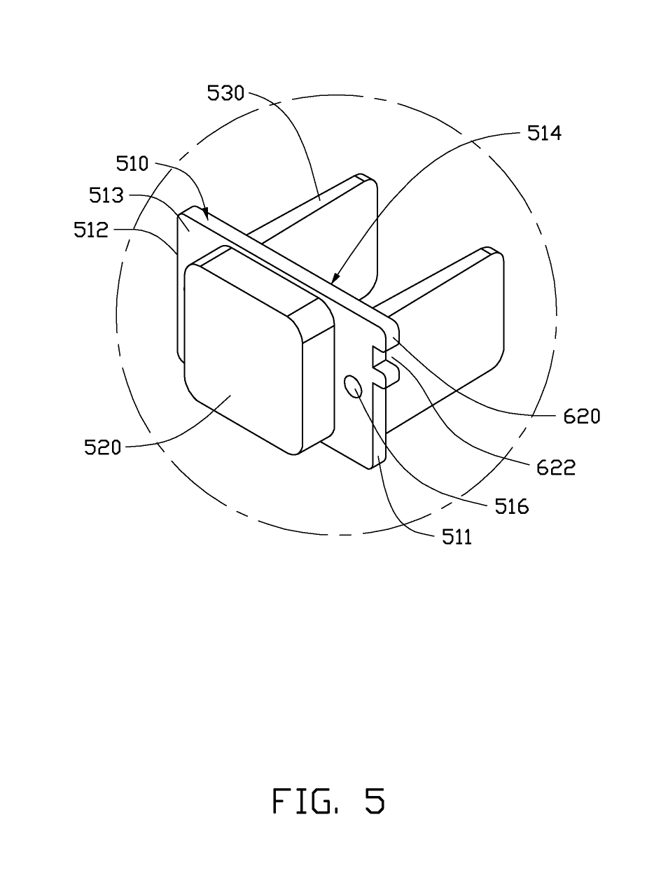

Referring to FIG. 5, the sensor window cover 50 includes a base 510 and a window 520 arranged on the base 510. The base 510 is substantially rectangular and includes a first end 511, and a second end 512 opposite to the first end 511. The base 510 defines two limiting holes 516. The limiting holes 516 are spaced from each other and are symmetrically arranged on the base 510. The limiting holes 516 correspond to and receive the limiting posts 114 respectively. The window 520 is arranged on a front surface 513 of the base 510 and is between the limiting holes 516. The size of the window 520 is slightly less than the size of the opening 112. When viewed from the front surface 513 of the base 510, the window 520 protrudes out of the front surface 513; when viewed from a rear surface 514 of the base 510, the window 520 is recessed in the rear surface 514 of the base 510. In the embodiment, the sensor window cover 50 is made of polymethyl methacrylate.

Furthermore, two supporting plates 530 are perpendicularly secured to the rear surface 514 of the base 510. The supporting plates 530 are parallel to each other and are arranged at opposite sides of the opening 112. In the embodiment, each supporting plate 530 is arranged between one of the limiting hole 516 and the opening 112.

The stopping mechanism 60 includes a resisting member 620, a first stopping member 640 and a second stopping member 660. Referring to FIG. 5, the resisting member 620 is secured to the first end 511 of the base 510. The resisting member 620 is arranged at an upper end of the first end 511 in the embodiment. An end of the resisting member 620 away from the first end 511 is recessed to form a substantially U-shaped receiving portion 622.

Referring also to FIG. 4, the first stopping member 640 and the second stopping member 660 are secured to the inner surface of the front wall 110. Longitudinal planes of the first and second stopping members 640, 660 are perpendicular to each other, and the distance between the first and second stopping members 640, 660 is slightly greater than the distance between the first and second ends 511, 512. When viewed in a direction perpendicular to the front wall 110, the first and second stopping members 640, 660 are arranged at opposite sides of the opening 112; when viewed in a direction parallel to the the front wall 110, the first and second stopping members 640, 660 are arranged at opposite sides of the connecting line where the limiting posts 114 are aligned, with the first stopping member 640 parallel to the connecting line and the second stopping member 660 perpendicular to the connecting line. The distance between an end of the first stopping member 640 adjacent to the opening 112 and the longitudinal plane of the second stopping member 660 is less than the distance between the second end 512 and the distal end of the resisting member 620, but is slightly greater than the distance between the second end 512 and the bottom of the receiving portion 622.

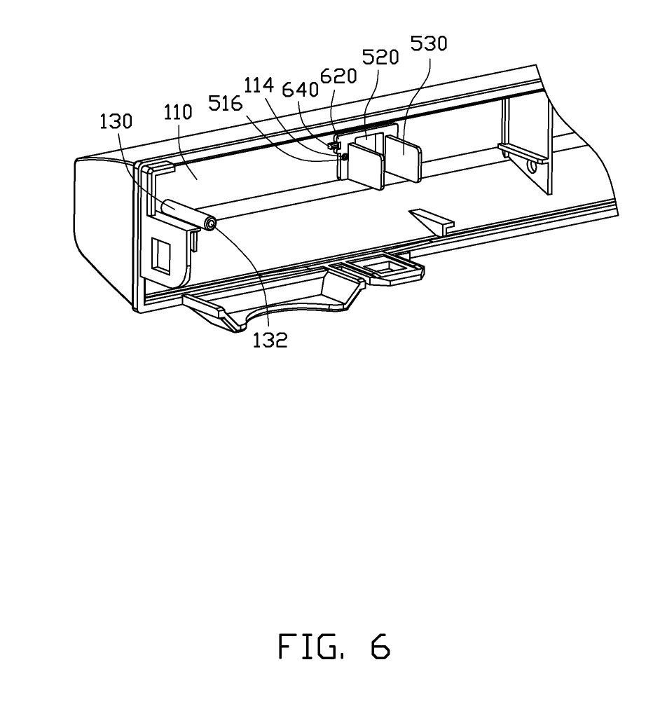

Referring to FIG. 6 in assembly, the limiting posts 114 are received in the corresponding limiting holes 516, and the window 520 is received in the opening 112 with the first stopping member 640 being received in the receiving portion 622 and the second stopping member 660 abutting the second end 512. The circuit board 30 is secured to the fixing posts 130 and further abuts ends of the supporting plates 530 away from the base 510 to prevent the sensor window cover 50 from disengaging with the front case 101. Because the distance between an end of the first stopping member 640 adjacent to the opening 112 and the longitudinal plane of the second stopping member 660 is less than the distance between the second end 512 and the distal end of the resisting member 620, when the sensor window cover 50 is installed reversely, the first stopping member 640 abut the second end 512 and the second stopping member 660 abut the resisting member 620 to prevent the window 520 from being received in the opening 112. Thus, by virtue of the stopping mechanism 60, the sensor window cover 50 is prevented from being installed reversely.

It is to be understood, even though information as to, and advantages of, the present embodiments have been set forth in the foregoing description, together with details of the structures and functions of the present embodiments, the disclosure is illustrative only; and that changes may be made in detail, especially in the matters of shape, size, and arrangement of parts within the principles of the present embodiments to the full extent indicated by the broad general meaning of the terms in which the appended claims are expressed.

What is claimed is:

1. An electronic device, comprising:
a housing defining an opening;
a signal receiving unit received in the housing;
a sensor window cover secured to the opening and corresponding to the signal receiving unit; and
a stopping mechanism comprising a resisting member secured to the sensor window cover, a first stopping member and a second stopping member arranged on opposite sides of the opening;
wherein the resisting member engages with the first stopping member to allow the sensor window cover to be secured to the opening when the sensor window cover is installed normally, and abuts the second stopping member to prevent the sensor window cover from being secured to the opening when the sensor window is installed reversely.

2. The electronic device of claim 1, wherein the sensor window cover comprises a base having a first end and a second end opposite to the first end, and a window arranged between the first and second ends and capable of being received in the opening.

3. The electronic device of claim 2, wherein the resisting member is secured to one of the first and second end.

4. The electronic device of claim 2, wherein at least one limiting post is arranged at a side of the opening, the base defines at least one limiting hole for receiving the at least one limiting post.

5. The electronic device of claim 2, further comprising a circuit board received in the housing, wherein the circuit board abut the base to secure the sensor window cover to the housing.

6. The electronic device of claim 5, wherein at least one supporting plate is secured to a surface of the base opposite to the window, the circuit board abuts ends of the at least one supporting plate away from the base to secure the sensor window cover to the housing.

7. The electronic device of claim 1, wherein the resisting member defines a receiving portion, the receiving portion receives the first stopping member to allow the sensor window cover to be secure to the opening when the sensor window cover is installed normally.

8. The electronic device of claim 2, wherein the distance between the distal end of the first stopping member and the second end is greater than the distance between an end of the first stopping member adjacent to the opening and the longitudinal plane of the second stopping member.

9. The electronic device of claim 2, wherein longitudinal planes of the first stopping member and the second stopping member are perpendicular to each other, and the distance between the limiting block and the stopping block is slightly greater than the distance between the first and second ends.

10. The electronic device of claim 9, wherein the distance between the second end and the bottom of the receiving portion is slightly less than the distance between an end of the first stopping member adjacent to the opening and the longitudinal plane of the second stopping member.
